(19) United States
(12) Patent Application Publication
(10) Pub. No.: US 2011/0031012 A1
(43) Pub. Date: Feb. 10, 2011

(54) PROTECTING APPARATUS FOR SOLID STATE DRIVE

(75) Inventors: Chih-Ming HUANG, Tu-Cheng (TW); Wei-Chao HUANG, Tu-Cheng (TW); Chung-Ping LIU, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/630,754

(22) Filed: Dec. 3, 2009

(30) Foreign Application Priority Data
Aug. 5, 2009 (CN) 200910305253.9

(51) Int. Cl. H05K 5/00

(52) U.S. Cl. 174/520

(57) ABSTRACT

A protecting apparatus includes a receiving box for receiving a solid state drive, and a cover pivotably connected to the receiving box. The receiving box includes a base. Two feet protrude down from a bottom of the base for fixing the receiving box to a motherboard. A through hole is defined in the base for allowing a connector of the motherboard to extend into the receiving box to electrically connect to the solid state drive. The protecting apparatus can protect the solid state drive from knock and loose.

### BACKGROUND

1. Technical Field

The present disclosure relates to a protecting apparatus for a solid state drive.

2. Description of Related Art

Generally, a solid state drive is directly connected to a motherboard of a computer without any protecting apparatus. When the motherboard is tested by an operator, the solid state drive may become loose in connection with the motherboard during the procedure or even damaged.

### BRIEF DESCRIPTION OF THE DRAWINGS

FIG. 1 is an exploded, isometric view of an embodiment of a protecting apparatus together with a solid state drive and a motherboard.

FIG. 2 is an inverted view of the protecting apparatus and the solid state drive of FIG. 1.

FIG. 3 is a partially assembled, isometric view of FIG. 1.

FIG. 4 is an assembled, isometric view of FIG. 3.

### DETAILED DESCRIPTION

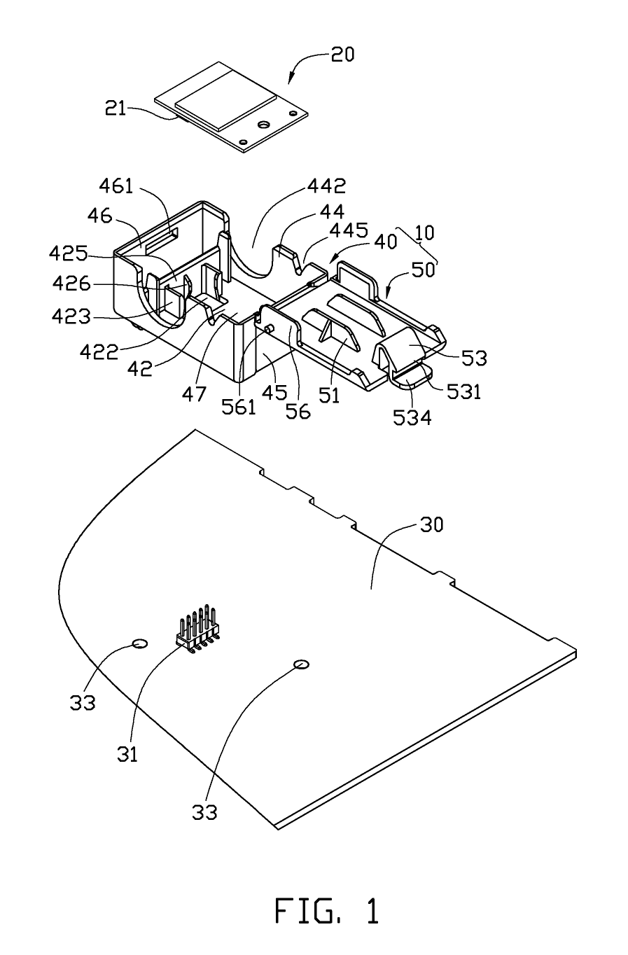

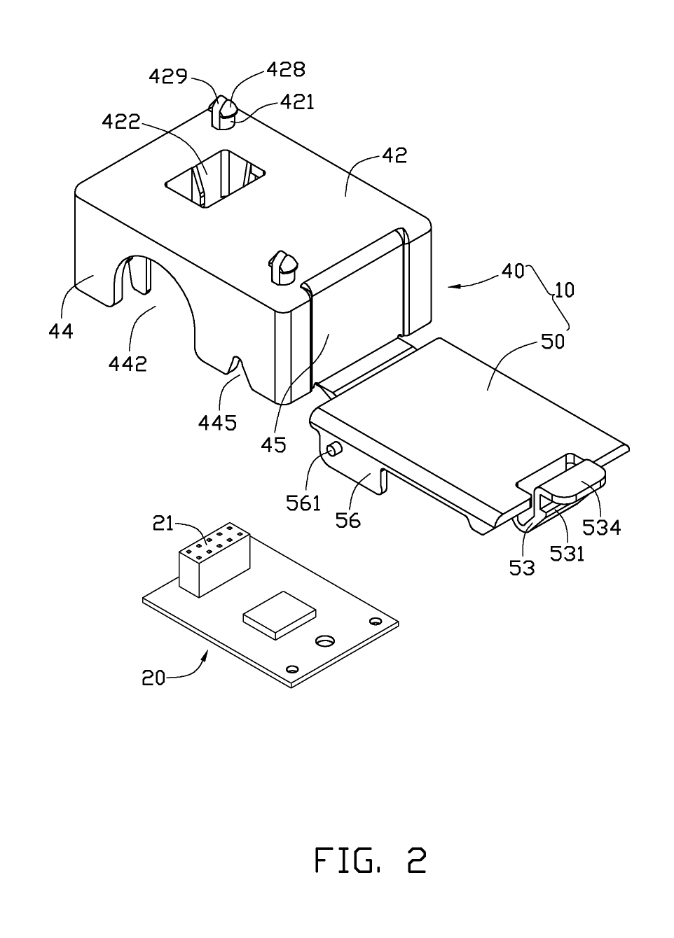

Referring to FIGS. 1 and 2, an embodiment of a protecting apparatus 10 is provided for protecting a solid state drive 20 mounted to a motherboard 30.

A first connector 21 is mounted to a bottom of the solid state drive 20.

Two fixing holes 33 are defined in the motherboard 30. A second connector 31, corresponding to the first connector 21, is mounted to the motherboard 30 between the fixing holes 33.

The protecting apparatus 10 includes a receiving box 40 and a cover 50.

The receiving box 40 includes a base 42, two sidewalls 44 perpendicularly extending up from opposite sides of the base 42, and a first end wall 45 and a second end wall 46 correspondingly extending up from opposite ends of the base 42. A receiving space 47 is bounded by the base 42, the sidewalls 44, the first end wall 45, and the second end wall 46. Two columnar feet 421, corresponding to the fixing holes 33 of the motherboard 30, protrude down from a bottom of the base 42. A cone-shaped flange 428 protrudes from a distal end of each foot 421, away from the base 42. A slot 429 is axially defined in each flange 428 and the corresponding foot 421, to bisect the foot 421 and the flange 428, and allow the foot 421 and the flange 428 to be elastic and contractile. A through hole 422 is defined in the base 42, corresponding to the second connector 31 of the motherboard 30. Two opposite C-shaped plates 423 correspondingly extend into the receiving space 47 from two portions of the base 42 bounding opposite sides of the through hole 422. A stop plate 425 extends from a portion of the base 42 bounding an end of the through hole 422. The stop plate 425 perpendicularly connects the plates 423, and higher than the plates 423. A supporting rib 426 having the same height as the plates 423, extends from the stop plate 425, above the through hole 422. Two openings 442 are correspondingly defined in tops of the sidewalls 44, adjacent to the through hole 422. Two notches 445 are correspondingly defined in the tops of the sidewalls 44, adjacent to the first end wall 45. A latching slot 461 is defined in the second end wall 46, adjacent to a top of the second end wall 46.

The cover 50 is pivotably connected to a top of the first end wall 45 of the receiving box 40. Two blocking ribs 51 are formed on an inner surface of the cover 50. A substantially U-shaped resilient latch 53 protrudes inwardly from an end of the cover 50, away from the first end wall 45. A latching portion 531 protrudes from the resilient latch 53, corresponding to the latching slot 461 of the second end wall 46 of the receiving box 40. An operating portion 534 extends from a distal end of the resilient latch 53, away from the first end wall 45. Two tabs 56 perpendicularly extend inwardly from opposite sides of the cover 50, adjacent to the first end wall 45. A protrusion 561 extends from an outer surface of each tab 56. In this embodiment, the cover 50 integrally extends from the receiving box 40, the cover 50 is pivotable relative to the receiving box 40 by elasticity. In another embodiment, the cover 50 may be pivotably connected to the receiving box 40 via a pivot.

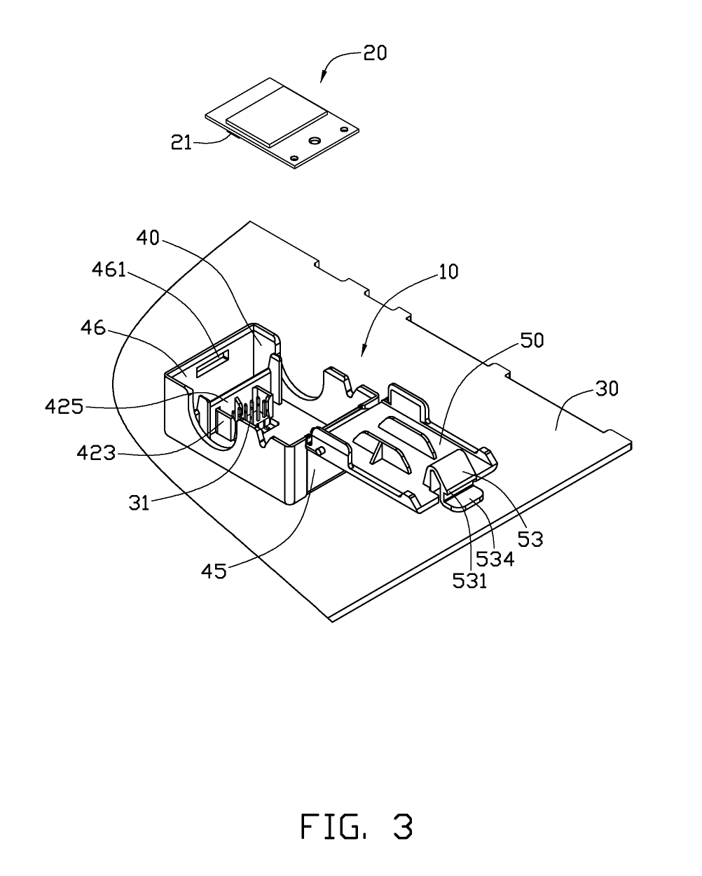

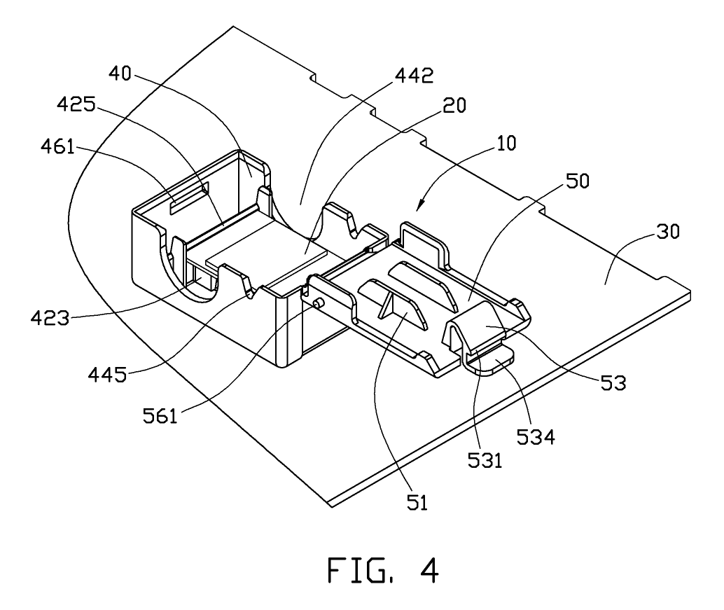

Referring to FIGS. 3 and 4, in assembly, the feet 421 of the receiving box 40 of the protecting apparatus 10 are inserted into the corresponding fixing holes 33 of the motherboard 30. The flanges 428 are contracted to pass through the corresponding fixing holes 33, and then are restored to engage with a bottom surface of the motherboard 30. Thereby, the protecting apparatus 10 is fixed to the motherboard 30. The second connector 31 of the motherboard 30 extends into the receiving box 40 through the through hole 422 of the base 42, and is bounded by the plates 423 and the stop plate 425. The solid state drive 20 is placed in the receiving space 47 of the receiving box 40, to allow the first connector 21 of the solid state drive 20 to be connected to the second connector 31 by the guiding of the plates 423 and the stop plate 425. The solid state drive 20 is supported on the plates 423 and the supporting rib 426, with an end of the solid state drive 20 abutting the stop plate 425. The cover 50 is rotated towards the receiving box 40, until the protrusions 561 of the tabs 56 correspondingly engage in the notches 445 of the sidewalls 44, the blocking ribs 51 abut a top of the solid state drive 20, and the latching portion 531 of the resilient latch 53 engages in the latching slot 461 of the second end wall 46. Thereby, the solid state drive 20 is fixed in the protecting apparatus 10. The protecting apparatus 10 can protect the solid state drive 20 from being knocked loose.

To take out the solid state drive 20, the operating portion 534 of the cover 50 of the protecting apparatus 10 is pulled, to allow the resilient latch 53 to deform to disengage the latching portion 531 from the latching slot 461 of the receiving box 40. The cover 50 is rotated away from the receiving box 40. Two fingers of an operator may be inserted into a space between the solid state drive 20 and the base 42 of the receiving box 40 through the openings 442 of the sidewalls 44, to pull the solid state drive 20 out of the receiving box 40.

It is to be understood, however, that even though numerous characteristics and advantages of the present disclosure have been set forth in the foregoing description, together with details of the structure and function of the disclosure, the disclosure is illustrative only, and changes may be made in details, especially in matters of shape, size, and arrangement of parts within the principles of the disclosure to the full extent indicated by the broad general meaning of the terms in which the appended claims are expressed.

What is claimed is:

1. A protecting apparatus for a solid state drive, comprising:
a receiving box to receive the solid state drive, the receiving box comprising a base, two feet protruding down from a bottom of the base for fixing the receiving box to a motherboard, the base defining a through hole therein, for allowing a connector of the motherboard to extend into the receiving box to electrically connect to the solid state drive; and
a cover pivotably connected to the receiving box, to cover the receiving box.

2. The protecting apparatus of claim 1, wherein each of the feet is columnar, a cone-shaped flange protrudes outwardly from a distal end of each of the feet away from the base, a slot is axially defined in each flange and a corresponding foot, to bisect the foot and the flange and allow the foot and the flange to be elastic and contractile.

3. The protecting apparatus of claim 1, wherein the receiving box further comprises a first end wall and a second end wall correspondingly extending up from opposite ends of the base, the cover is pivotably connected to the first end wall, a resilient latch protrudes inwardly from an end of the cover away from the first end wall, a latching slot is defined in the second end wall to engage with the resilient latch.

4. The protecting apparatus of claim 3, wherein the resilient latch is substantially U-shaped, a latching portion protrudes outwardly from the resilient latch to engage in the latching slot of the second end wall, and an operating portion extends outwardly from a distal end of the resilient latch away from the first end wall.

5. The protecting apparatus of claim 1, wherein at least one blocking rib is formed on an inner surface of the cover, to abut a top of the solid state drive.

6. The protecting apparatus of claim 1, wherein the receiving box further comprises two sidewalls perpendicularly extending up from opposite sides of the base, an opening is defined in a top of each of the sidewalls, adjacent to the through hole.

7. The protecting apparatus of claim 6, wherein two opposite C-shaped plates correspondingly extend into the receiving box from two portions of the base bounding opposite sides of the through hole.

8. The protecting apparatus of claim 7, wherein a stop plate extends from a portion of the base bounding an end of the through hole, the stop plate perpendicularly connects the C-shaped plates, and higher than the plates.

9. The protecting apparatus of claim 8, wherein a supporting rib having the same height as the C-shaped plates, extends from a side of the stop plate, above the through hole.

10. The protecting apparatus of claim 6, wherein a notch is defined in the top of each of the sidewalls, two tabs perpendicularly extend inwardly from opposite sides of the cover, and a protrusion extends from an outer surface of each of the tabs to engage in the notch of a corresponding sidewall.
